(19) United States
(12) Patent Application Publication
(10) Pub. No.: US 2024/0074439 A1
(43) Pub. Date: Mar. 7, 2024

(54) LOW-LABOR INTENSITY AND SIMPLE METHOD FOR REDUCING Cd CONTENT OF RICE AND USE THEREOF

(71) Applicants: INSTITUTE OF SOIL SCIENCE, CHINESE ACADEMY OF SCIENCES, Jiangsu (CN); JIANGXI JIEDI ENVIRONMENTAL TREATMENT & ECOLOGICAL TECHNOLOGY CO., LTD, Jiangxi (CN)

(72) Inventors: Jing ZHOU, Nanjing Jiangsu (CN); Ruizhi XIA, Nanjing Jiangsu (CN); Jiani LIANG, Nanjing Jiangsu (CN); Mengli LIU, Nanjing Jiangsu (CN); Jun ZHOU, Nanjing Jiangsu (CN)

(21) Appl. No.: 17/617,334

(22) PCT Filed: Jun. 1, 2021
(86) PCT No.: PCT/CN2021/097651

§ 371 Date: Dec. 8, 2021

(30) Foreign Application Priority Data
May 24, 2021 (CN) 202110563467.7

(51) Int. Cl. A01N 59/00; A01C 1/00; A01N 59/16

(52) U.S. Cl. CPC A01N 59/00; A01C 1/00; A01N 59/16

(57) ABSTRACT

A seed soaking agent for reducing Cd content of rice and a low-labor intensity and simple method for reducing Cd content of rice are disclosed. The method includes mixing a seed and a seed soaking agent, and soaking the seed, to obtain a soaked seed; sowing the soaked seed, and reaping to obtain rice with a low Cd content, wherein an active ingredient of the seed soaking agent includes a trace element required by plants, the trace element includes selenium element, silicon element, zinc element or iron element, or a mixture of selenium element and iron element, a mixture of selenium element and silicon element, or a mixture of selenium element and zinc element.

### CROSS REFERENCE TO RELATED APPLICATION

This application claims the priority of Chinese Patent Application No. 202110563467.7, entitled “low-labor intensity and simple method for reducing Cd content of rice and use thereof” filed with the Chinese National Intellectual Property Administration on May 24, 2021, which is incorporated herein by reference in its entirety.

### TECHNICAL FIELD

The present disclosure relates to the technical field of prevention and control of the heavy metal pollution, in particular to a low-labor intensity and simple method for reducing Cd content of rice and use thereof.

### BACKGROUND

Cd is a non-essential element in organisms, and is regarded as the most biologically toxic heavy metal because of its high mobility, high toxicity, high accumulation and difficulty in elimination. After entering soil, heavy metal Cd could be easily absorbed by plants and enriched therein because of its high bioactivity. Meanwhile, Cd is thus transferred through food chains, which poses a threat to human health, including causing osteoporosis, arteriosclerosis, and kidney damage.

Rice is one of the main food products in China. Cd pollution in soil will cause the Cd content in rice to exceed the standard, which will cause harm to human health. Thus, it is particularly important to control the Cd content in rice. There are many measures to prevent rice Cd from exceeding the standard. The contaminated soil is mainly rehabilitated to achieve the purpose of safe production. A more effective method for remediation and treatment of Cd pollution in farmland is to apply soil passivation materials, including lime, fly ash, hydroxyapatite, organic fertilizers, etc., to increase the pH value of soil, increase adsorption sites in soil, and reduce the activity of Cd in soil, thereby preventing the Cd absorption by roots of rice. However, due to the strong biological mobility of Cd, some Cd ions still can be absorbed by roots of rice, and then transferred to stems, leaves, and kernels. In addition, the passivation stability decreases with the extension of time after applying passivation materials, and heavy metal Cd in soil may be reactivated, and then transferred to the edible portions of the crop. Especially Cd in the acid paddy soil is more likely to be reactivated because of acid deposition and other reasons.

For large areas of heavy metals-contaminated farmland, how to obtain rice with a Cd content in conformity with the standard by the lowest cost and the most convenient method has become a problem that needs to be solved urgently.

### SUMMARY

To resolve the above problem, the present disclosure provides a low-labor intensity and simple method for reducing Cd content of rice and use thereof. The method allows for production of rice with a Cd content in conformity with the standard by a reduced-cost and simple-operation method.

To achieve the above object, the present disclosure provides the following technical solutions:

The present disclosure provides a seed soaking agent for reducing Cd content of rice, an active ingredient of which comprises a trace element required by plants,
wherein the trace element comprises one of selenium element, silicon element, zinc element, and iron element, or a mixture of selenium element with one selected from the group consisting of iron element, silicon element, and zinc element;
under the condition that the trace element is selenium element, a selenium element concentration in the seed soaking agent is in the range of 0.5-6 mg/L;
under the condition that the trace element is silicon element, a silicon element concentration in the seed soaking agent is in the rang of under the condition that the trace element is zinc element, a zinc element concentration in the seed soaking agent is in the range of 0.25-0.75 mol/L;
under the condition that the trace element is iron element, an iron element concentration in the seed soaking agent is in the range of 3-5 mg/L;
under the condition that the trace element is a mixture of selenium element and iron element, in the seed soaking agent, a selenium element concentration is in the range of 4-6 mg/L, and an iron element concentration is in the range of 3-5 mg/L;
under the condition that the trace element is a mixture of selenium element and silicon element, in the seed soaking agent, a selenium element concentration is in the range of 4-6 mg/L, and a silicon element concentration is in the range of 1.5-5 mmol/L;
under the condition that the trace element is a mixture of selenium element and zinc element, in the seed soaking agent, a selenium element concentration is in the range of 4-6 mg/L, and a zinc element concentration is in the range of 0.25-0.75 mol/L.

In some embodiments, under the condition that the trace element comprises selenium element, a source of the selenium element includes Na₂SeO₃.

In some embodiments, under the condition that the trace element comprises silicon element, a source of the silicon element includes silicic acid.

In some embodiments, under the condition that the trace element comprises zinc element, a source of the zinc element includes ZnSO₄·7H₂O.

In some embodiments, under the condition that the trace element comprises iron element, a source of the iron element includes FeSO₄·7H₂O.

The present disclosure also provides a low-labor intensity and simple method for reducing Cd content of rice, comprising
mixing a seed and a seed soaking agent, and soaking the seed, to obtain a soaked seed;
sowing the soaked seed; and
reaping to obtain rice with a low Cd content,
wherein an active ingredient of the seed soaking agent comprises a trace element required by plants,
said trace element comprises selenium element, silicon element, zinc element or iron element, or a mixture of selenium element and iron element, a mixture of selenium element and silicon element, or a mixture of selenium element and zinc element;
under the condition that the trace element is selenium element, a selenium concentration in the seed soaking agent is in the range of 0.5-6 mg/L;
under the condition that the trace element is silicon element, a silicon element concentration in the seed soaking agent is in the rang of 1.5-5 mmol/L;
under the condition that the trace element is zinc element, a zinc element concentration in the seed soaking agent is in the rang of 0.25-0.75 mol/L;
under the condition that the trace element is iron element, an iron element in the seed soaking agent is in the range of 3-5 mg/L;
under the condition that the trace element is a mixture of selenium element and iron element, in the seed soaking agent, a selenium concentration is in the range of 4-6 mg/L, and an iron concentration is in the range of 3-5 mg/L;
under the condition that the trace element is a mixture of selenium element and silicon element, in the seed soaking agent, a selenium element concentration is in the range of 4-6 mg/L, and a silicon element concentration is in the range of 1.5-5 mmol/L;
under the condition that the trace element is a mixture of selenium element and zinc element, in the seed soaking agent, a selenium element concentration is in the range of 4-6 mg/L, and a zinc element concentration is in the range of 0.25-0.75 mol/L.

In some embodiments, a mass-volume ratio of the seed to the seed soaking agent is in the range of 1 g:(4-7) mL; the seed has a moisture content of 12%-14%.

In some embodiments, under the condition that the trace element comprises selenium element, a source of the selenium element includes Na₂SeO₃;
under the condition that the trace element comprises silicon element, a source of the silicon element includes silicic acid;
under the condition that the trace element comprises zinc element, a source of the zinc element includes ZnSO_{4·}7H₂O;
under the condition that the trace element comprises iron element, a source of the iron element includes FeSO₄·7H₂O.

In some embodiments, under the condition that the trace element is silicon element, the seed soaking agent is prepared by a process comprising
mixing silicic acid with water, and sonicating the resulting mixture to obtain the seed soaking agent.

In some embodiments, under the condition that the trace element is a mixture of selenium element and silicon element, the seed soaking agent is prepared by a process comprising
mixing silicic acid with water, and sonicating the resulting mixture, to obtain a silicic acid suspension; and
mixing the silicic acid suspension with Na₂SeO₃, to obtain the seed soaking agent.

In some embodiments, the sonicating is conducted at 30° C. In some embodiments, the sonicating is conducted for 7-8 hours.

In some embodiments, the method further comprises after mixing the seed and the seed soaking agent, leaving the seed to stand. In some embodiments, leaving the seed to stand is conducted in the dark at a temperature of 24-29° C. for 24-26 hours.

In some embodiments, the method further comprises before sowing the soaked seed, pre-germinating the soaked seed. In some embodiments, pre-germinating the soaked seed is conducted for 3-5 days.

In some embodiments, the method further comprises before mixing the seed and the seed soaking agent, disinfecting the seed. In some embodiments, disinfecting the seed comprises
disinfecting the seed with an aqueous ethanol solution, and an aqueous sodium hypochlorite solution in sequence to obtain a disinfected seed, and rinsing the disinfected seed with sterile water,
wherein the aqueous ethanol solution has an ethanol volume concentration of 65%-75%, and the aqueous sodium hypochlorite solution has an available chlorine content of 5%-7%.

In some embodiments, disinfecting the seed with an aqueous ethanol solution is conducted for 4-6 min. In some embodiments, disinfecting the seed with an aqueous sodium hypochlorite solution is conducted for 25-35 min.

The present disclosure also provides use of the method as described in the above technical solutions for reducing Cd content of rice grown in Cd-contaminated soil.

Beneficial Technical Effects:

The present disclosure provides a low-labor intensity and simple method for reducing Cd content of rice, which includes mixing a seed and a seed soaking agent, and soaking the seed, to obtain a soaked seed, sowing the soaked seed, and reaping to obtain rice with a low Cd content, wherein an active ingredient of the seed soaking agent comprises a trace element required by plants, and said trace element includes selenium element, silicon element, zinc element or iron element, or a mixture of selenium element and iron element, a mixture of selenium element and silicon element, or a mixture of selenium element and zinc element; under the condition that the trace element is selenium element, a selenium element concentration in the the seed soaking agent is in the range of 0.5-6 mg/L; under the condition that the trace element is silicon element, a silicon element concentration in the seed soaking agent is in the range of 1.5-5 mmol/L; under the condition that the trace element is zinc element, a zinc element concentration in the seed soaking agent is in the range of 0.25-0.75 mol/L; under the condition that the trace element is iron element, an iron element concentration in the seed soaking agent is in the range of 3-5 mg/L; under the condition that the trace element is a mixture of selenium element and iron element, in the seed soaking agent, a selenium element concentration is in the range of 4-6 mg/L, and an iron element concentration is in the range of 3-5 mg/L; under the condition that the trace element is a mixture of selenium element and silicon element, in the seed soaking agent, a selenium element concentration is in the range of 4-6 mg/L, and a silicon element concentration is in the range of 1.5-5 mmol/L; under the condition that the trace element is a mixture of selenium element and zinc element, in the seed soaking agent, a selenium element concentration is in the range of 4-6 mg/L, and a zinc element concentration is in the range of 0.25-0.75 mol/L. In the present disclosure, the seed soaking agent and the seed is mixed, and the seed is soaked. Therefore, the present disclosure allows for production of rice with a Cd content in conformity with the standard by the lowest-cost and the most convenient method.

### BRIEF DESCRIPTION OF THE DRAWINGS

FIG. 1 shows Cd contents in kernels harvested after different treatments in Use Example 1.

FIG. 2 shows Cd contents in roots of rice plants grown from seeds treated by different processes in Use Example 1.

FIG. 3 shows Cd contents in stems of rice plants grown from seeds treated by different processes in Use Example 1.

FIG. 4 shows Cd contents in leaves of rice plants grown from seeds treated by different processes in Use Example 1.

FIG. 5 shows Cd contents in kernels harvested after different treatments in Use Example 2.

FIG. 6 shows Cd contents in roots of rice plants grown from seeds treated by different processes in Use Example 2.

FIG. 7 shows Cd contents in stems of rice plants grown from seeds treated by different processes in Use Example 2.

FIG. 8 shows Cd contents in leaves of rice plants grown from seeds treated by different processes in Use Example 2.

FIG. 9 shows Cd contents in kernels harvested after different treatments in Use Example 3.

FIG. 10 shows Cd contents in roots of rice plants grown from seeds treated by different processes in Use Example 3.

FIG. 11 shows Cd contents in stems of rice plants grown from seeds treated by different processes in Use Example 3.

FIG. 12 shows Cd contents in leaves of rice plants grown from seeds treated by different processes in Use Example 3.

FIG. 13 shows Cd contents in kernels harvested after different treatments in Use Example 4.

FIG. 14 shows Cd contents in roots of rice plants grown from seeds treated by different processes in Use Example 4.

FIG. 15 shows Cd contents in stems of rice plants grown from seeds treated by different processes in Use Example 4.

FIG. 16 shows Cd contents in leaves of rice plants grown from seeds treated by different processes in Use Example 4.

FIG. 17 shows Cd contents in kernels harvested from seeds (Chuangliangyou 276) soaked with soaking seed agents having different Se concentrations in Use Example 5.

FIG. 18 shows Cd contents in kernels harvested from seeds (Wuyouzhanhua) soaked with soaking seed agents having different Se concentrations in Use Example 5.

FIG. 19 shows Se contents in kernels harvested from seeds soaked with soaking seed agents having different Se concentrations in Use Example 6.

FIG. 20 shows Cd contents in kernels harvested from seeds (different varieties) soaked with soaking seed agents having different Se concentrations in Use Example 7.

### DETAILED DESCRIPTION OF THE EMBODIMENTS

The present disclosure provides a low-labor intensity and simple method for reducing Cd content of rice, which includes the steps of mixing a seed and a seed soaking agent, and soaking the seed, to obtain a soaked seed;
sowing the soaked seed; and
reaping to obtain rice with a low Cd content,
wherein an active ingredient of the seed soaking agent comprises a trace element required by plants,
said trace element includes selenium element, silicon element, zinc element or iron element, or a mixture of selenium element and iron element, a mixture of selenium element and silicon element, or a mixture of selenium element and zinc element;
under the condition that the trace element is selenium element, a selenium element concentration in the seed soaking agent is in the range of 0.5-6 mg/L;
under the condition that the trace element is silicon element, a silicon element concentration in the seed soaking agent is in the range of 1.5-5 mmol/L;
under the condition that the trace element is zinc element, a zinc element concentration in the seed soaking agent is in the range of 0.25-0.75 mol/L;
under the condition that the trace element is iron element, an iron element concentration in the seed soaking agent is in the range of 3-5 mg/L;
under the condition that the trace element is a mixture of selenium element and iron element, in the seed soaking agent, a selenium element concentration is in the range of 4-6 mg/L, and an iron element concentration is in the range of 3-5 mg/L;
under the condition that the trace element is a mixture of selenium element and silicon element, in the seed soaking agent, a selenium element concentration is in the range of 4-6 mg/L, and a silicon element concentration is in the range of 1.5-5 mmol/L; and
under the condition that the trace element is a mixture of selenium element and zinc element, in the seed soaking agent, a selenium element concentration is in the range of 4-6 mg/L, and a zinc element concentration is in the range of 0.25-0.75 mol/L.

Unless otherwise specified, in the present disclosure, there is no limitation on the source of each component in the seed soaking agent, and commercially available products well known to those skilled in the art may be used.

In the present disclosure, the seed is mixed with the seed soaking agent and soaked, to obtain a soaked seed. In some embodiments of the present disclosure, before mixing the seed with the seed soaking agent, the method further comprises disinfecting the seed. In some embodiments, disinfecting the seed is performed by a process including the following steps: disinfecting the seed with an aqueous ethanol solution, and an aqueous sodium hypochlorite solution in sequence to obtain a disinfected seed, and rinsing the disinfected seed with sterile water. In some embodiments, the aqueous ethanol solution has an ethanol volume concentration of 65%-75%, and preferably 70%. In some embodiments, disinfecting the seed with an aqueous ethanol solution is performed for 4-6 min, and preferably 5 min. In some embodiments, the aqueous sodium hypochlorite solution has an available chlorine content of 5%-7%, and preferably 6%. In some embodiments, disinfecting the seed with an aqueous sodium hypochlorite solution is performed for 25-35 min, and preferably 30 min. In some embodiments, rinsing the disinfected seed to with sterile water is performed for 5-6 times.

In the present disclosure, under the condition that the trace element is selenium element, a selenium element concentration in the seed soaking agent is in the range of 0.5-6 mg/L, preferably 1-5.5 mg/L, and more preferably 5 mg/L. In some embodiments, a source of the selenium element includes Na₂SeO₃. In some embodiments, a purity of Na₂SeO₃ is greater than 99%. In some embodiments, the seed soaking agent is prepared by a process including the step of mixing Na₂SeO₃ with water to obtain the seed soaking agent. In the present disclosure, there is no limitation on the means for mixing, and any means for mixing well known to those skilled in the art may be used.

According to the present disclosure, a solution having a suitable selenium element concentration is used to soak the rice seed, which could improve activity of antioxidant enzymes (superoxide dismutase SOD, catalase CAT, and Glutathione Oxidase GSH-Px) and proline (Pro) content, reduce hydrogen peroxide (H₂O₂) and malondialdehyde (MDA) contents in roots and leaves of the rice plant, and advantageously promote the formation of insoluble Cd-selenium complex in the roots of the rice plant, thereby reducing the content of bioavailable Cd in the soil solution and inhibiting the absorption and transportation of Cd by rice. In addition, it could also increase the reactive oxygen species ROS of rice cells, reduce the mitochondrial membrane potential, and increase the lignin content of rice plants and the thickness of cell wall. In addition, soaking the seed with selenium element could also reduce the expression of Cd uptake-related genes (OsNramp5) and transport-related genes (OsLCT1) in the rice plant, and activate the expression of lignin synthesis-related genes (OsPAL, OsCoMT; and Os4CL3), thereby adjusting the synthesis of lignin and the expression of Cd-related genes to reduce the absorption and transport of Cd by the rice plants, thereby reducing Cd content in rice.

In the present disclosure, under the condition that the trace element is silicon element, the silicon element concentration in the seed soaking agent is in the range of 1.5-5 mmol/L, preferably 1.8-4 mmol/L, and more preferably 2 mmol/L. In some embodiments, a source of the silicon element includes silicic acid. In some embodiments, the purity of the silicic acid is greater than 99%. In some embodiments, the seed soaking agent is prepared by a process including the steps of mixing silicic acid with water, and sonicating to obtain the seed soaking agent. In some embodiments, the sonicating is performed at 30° C. In some embodiments, the sonicating is performed for 7-8 h, preferably 7.5 h. In some embodiments, the apparatus for sonicating includes an ultrasonic cleaner.

In the present disclosure, there is no limitation on the source of the ultrasonic cleaner, and commercially available products well known to those skilled in the art may be used. In the present disclosure, by sonication, silicic acid is uniformly dispersed in water.

In the present disclosure, by using a solution with a suitable silicon element concentration to soak the rice seed, it reduces Cd uptake and transport in rice after growth, by down-regulating Cd transporter genes; by improving the antioxidant enzyme activity, it mitigates Cd-induced oxidative stress, reduces the increase in activity of Cd-induced superoxide dismutase (SOD), glutathione peroxidase enzyme (GSH-Px) and ascorbate peroxidase (APX); the contents of malondialdehyde (MDA), hydrogen peroxide (H₂O₂), and oxygen (O₂) in the rice plant under Cd stress are decreased, thereby relieving Cd-induced oxidative stress; the chlorophyll content of rice leaves is increased; root vitality is increased, thereby increasing resistance to heavy metals, and reducing Cd accumulation and toxicity of Cd in rice plants. In addition, silicon element could improve growth parameters of rice, and protect rice from cell death and electrolyte leakage induced from toxic Cd. By promoting the synthesis of pectin and exchange capacity between pectin methyl esterase and cation in suspension cell of the rice, silicon element plays an important role in maintaining cell wall integrity under the heavy metal stress, thereby retaining Cd in the rice root and limiting the transport of Cd to the above-ground portion of rice plant.

In the present disclosure, under the condition that the trace element is zinc element, the zinc element concentration in the seed soaking agent is in the range of 0.25-0.75 mol/L, preferably 0.5 mol/L. In some embodiments, a source of the zinc element includes ZnSO₄·7H₂O. In some embodiments, a purity of ZnSO₄·7H₂O is greater than 99%. In some embodiments, the seed soaking agent is prepared by a process including the step of mixing ZnSO₄·7H₂O with water to obtain the seed soaking agent. In the present disclosure, there is no limitation on the means for mixing, and any means for mixing well known to those skilled in the art may be used.

In the present disclosure, by using a solution with a suitable zinc element concentration to soak the rice seed, the antagonistic effect of zinc on Cd reduces the absorption and transport ability of seeds and rice plants to Cd, and meanwhile could increase the content of chlorophyll a, b, and a+b in leaves of the grown rice plants, enhance the activity of superoxide dismutase (SOD), peroxidase (POD), catalase (CAT), reduce malondialdehyde (MDA) content, and increase the content of soluble protein and soluble sugar, thereby increasing the activity of antioxidant enzyme during the growth of rice, slowing down lipid peroxidation, enhancing the level of material metabolism, and thereby reducing the Cd content in rice.

In the present disclosure, under the condition that the trace element is iron element, the iron element concentration in the seed soaking agent is in the range of 3-5 mg/L, preferably 4 mg/L. In some embodiments, a source of iron includes FeSO₄·7H₂O. In some embodiments, a purity of FeSO₄·7H₂O is greater than 98%. In some embodiments, the seed soaking agent is prepared by a process including the step of mixing FeSO₄·7H₂O with water to obtain the seed soaking agent. In the present disclosure, there is no limitation on means for mixing, and any means for mixing well known to those skilled in the art may be used.

In the present disclosure, by using a solution with a suitable iron element concentration to soak the rice seed, it could not only enhance the activity of antioxidant enzyme in the grown rice plant, but also increase the photosynthetic efficiency of the rice, and increase the height, dry weight, chlorophyll concentration, and gas exchange properties of the rice plant under Cd stress. By enhancing the physiological indicators of the rice plant, the toxic effect induced by Cd is alleviated. In addition, during the nutritional growth stage of rice, iron and Cd are absorbed by specific root transporters and transported to the above-ground portions through the xylem-phloem transport system. By soaking seeds with an solution with a suitable iron element concentration, the expression of gene for Cd transport in xylem and phloem, i.e. OsIRT1, OsNRAMP1 and OsNRAMP5 could be suppressed. In addition, by soaking seeds with a solution with a suitable iron element concentration, phytochelatin (PC) of rice seedlings cells could be increased, which is conducive to the chelation with Cd in the cell vacuole, thereby reducing the absorption of Cd by rice plants, thereby reducing the Cd content of rice.

In the present disclosure, under the condition that the trace elements are selenium element and iron element, in the seed soaking agent, a selenium element concentration is in the range of 4-6 mg/L, preferably 5 mg/L, and an iron element concentration is in the range of 3-5 mg/L, preferably 4 mg/L. In some embodiments, a source of the selenium element includes Na₂SeO₃. In some embodiments, a source of the iron element includes FeSO₄·7H₂O. In some embodiments, a purity of Na₂SeO₃ is greater than 99%. In some embodiments, a purity of FeSO₄·7H₂O is greater than 98%. In some embodiments, the seed soaking agent is prepared by a method including the step of mixing Na₂SeO₃ and FeSO₄·7H₂O with water to obtain the seed soaking agent. In the present disclosure, there is no limitation on means for mixing, and any means for mixing well known to those skilled in the art may be used.

In the present disclosure, by using a solution with a suitable selenium element concentration and iron element concentration to soak rice seed, it could enhance the activity of antioxidant enzyme in the grown rice plant, and improve resistance to heavy metals. Specifically, under the function of selenium element, SOD and CAT activities are stimulated by scavenging superoxide anion and H₂O₂, and radial oxygen of rice plant root system are enhanced; iron element could promote the formation of iron plaque on the root surface. The combination of the two elements could promote the formation of iron plaque on the root surface by increasing radial oxygen of the rice root system, which reduces the absorption of Cd by rice plants, thereby reducing the Cd content of rice.

In the present disclosure, under the condition that the trace elements are selenium element and silicon element, in the seed soaking agent, a selenium element concentration is in the range of 4-6 mg/L, and preferably 5 mg/L; a silicon element concentration is in the range of 1.5-5 mmolg/L, preferably 1.8-4 mmol/L, and more preferably 2 mmol/L.

In some embodiments, a source of the selenium element includes Na₂SeO₃. In some embodiments, a source of the silicon element includes silicic acid. In some embodiments, a purity of Na₂SeO₃ is greater than 99%. In some embodiments, a purity of silicic acid is greater than 99%.

In some embodiments, the soaking agent is prepared by a process including the steps of mixing silicic acid with water and sonicating the resulting mixture to obtain a silicic acid suspension, and mixing the silicic acid suspension with Na₂SeO₃ to obtain the seed soaking agent. In the present disclosure, there is no limitation on the means for mixing, and any means for mixing well known to those skilled in the art may be used. In the present disclosure, both the silicon element and the selenium element could effectively alleviate the toxicity of Cd, and silicon element and selenium element have a strong synergistic effect. In the present disclosure, by using a solution with a suitable selenium element concentration and silicon element concentration to soak the rice seed, it is possible to promote the growth of the rice plant, reduce the content of malondialdehyde (MDA) in roots and above-ground portions, and reduce Cd transport factor. In addition, the combination of silicon element and selenium element could increase the content of glutathione (GSH) and phytochelatin (PC) in cell walls and organelles in root, resulting in that PC—Cd is isolated into vacuoles, regulate the relative expression of OsNramp1 and OsHMA3 in rice, and promote the isolation of Cd in cell walls and vacuoles, down-regulate OsHMA2 relative expression, suppress the transport of Cd, and reduce the accumulation of Cd in rice seedlings. Thereby, Cd is sequestered in walls and organelles of the rice plant, thereby reducing the transfer of Cd to the above-ground portion of the rice.

In the present disclosure, under the condition that the trace elements are selenium element and zinc element, in the seed soaking agent, a selenium element concentration is in the range of 4-6 mg/L, preferably 5 mg/L, and a zinc element concentration is in the range of 0.25-0.75 mol/L, preferably 0.5 mol/L. In some embodiments, a source of the selenium element includes Na₂SeO₃. In some embodiments, a source of the zinc element includes ZnSO₄·7H₂O. In some embodiments, a purity of the Na₂SeO₃ is greater than 99%. In some embodiments, a purity of the ZnSO₄·7H₂O is greater than 99%. In some embodiments, the seed soaking agent is prepared by a method including the step of mixing Na₂SeO₃ and ZnSO₄·7H₂O with water to obtain the seed soaking agent. In the present disclosure, there is no limitation on means for mixing, and any means for mixing well known to those skilled in the art may be used. In the present disclosure, by using a solution with a suitable selenium element concentration and zinc element concentration to soak the rice seed, it could not only reduce the absorption and transport ability of seeds and rice plants to Cd by the antagonistic effect of zinc on Cd, but also could increase the antioxidant capacity of rice plants. Meanwhile, by minimizing the production of reactive oxygen species and inhibiting cell oxidative damage, it could improve the resistance to heavy metals, thereby reducing the ability of the rice plant to absorb and transport Cd, thereby reducing the Cd content of rice.

In some embodiments of the present disclosure, a mass-volume ratio of the seed to the seed soaking agent is in the range of 1 g:(4-7) mL, more preferably 1 g: 5 mL. In some embodiments, the moisture content of the seed before soaking is in the range of 12% to 14%.

In some embodiments of the present disclosure, the method further includes after mixing the seed and the seed soaking agent, leaving the seed to stand, to obtain the soaked seed. In some embodiments, leaving the seed to stand is conducted in the dark. In some embodiments, leaving the seed to stand is conducted for 24-26 hours, and preferably 25 hours. In some embodiments, leaving the seed to stand is conducted at a temperature of 24-29° C., preferably 25-27° C., and more preferably 26° C.

After the soaked seed is obtained, according to the present disclosure, the soaked seed is sown, and cultivated, to obtain a plant which exhibits great tolerance to Cd. In some embodiments of the present disclosure, the method further includes before sowing the soaked seed, pre-germinating the soaked seed. In some embodiments, pre-germinating the soaked seed is conducted for 3-5 days, and preferably 4 days. In the present disclosure, there is no limitation on the means for pre-germinating, and any means for pre-germinating well known to those skilled in the art may be used.

In some embodiments of the present disclosure, a means for sowing includes a mechanical direct-sowing, hand direct-sowing, dry direct-sowing, direct-sowing in water, or transplanting after seedling.

In the present disclosure, by mixing a soaking seed agent containing trace elements required by plants in a suitable concentration with rice seed and soaking the rice seed, it could not only reduce the absorption of Cd by plant roots, but also reduce the transport of Cd from plant root to other portions, thereby improving plant tolerance to Cd. In addition, the method of the present disclosure makes it possible to obtain rice with a Cd content in conformity with the standard by the lowest-cost and the most convenient method, and allows that brown rice harvested from the rice plant which is grown in Cd-contaminated soil has a Cd content significantly lower than the national food safety standards-pollutant limit standard in food of 0.2 mg/kg. Also, it saves a lot of manpower and material resources, and is completely suitable for popularization and use in the field of prevention and control technology of the heavy metal pollution in China's rice and other bulk agricultural products.

The present disclosure also provides use of the method as described in the above technical solution in reducing the Cd content of rice which is grown in Cd-contaminated soil.

In order to further illustrate the present disclosure, a low-labor intensity and simple method for reducing Cd content of rice and use thereof according to the present disclosure will be described in detail below in conjunction with examples, but these examples should not be understood as limiting the protection scope of the present disclosure.

### Example 1

A low-labor intensity and simple method for reducing Cd content of rice was performed by the following pot experiment:

The pot experiment was carried out in the greenhouse of the Institute of Botany, Chinese Academy of Sciences, Jiangsu Province. The soil to be tested was a hydromorphic paddy soil with excessive Cd. Basic physical and chemical properties thereof are shown in Table 1. According to “Soil Environmental Quality Risk Control Standard for Soil Contamination of Agricultural Land (GB 15618-2018), the Cd content in soil between the risk screening values and risk intervention values of Cd in soil of agricultural land represents slight and moderate contamination of soil. 80% of Cd-contaminated cultivated land in China was within this range. The rice to be tested, i.e. Chuangliangyou 276 is the main variety recommended by Jiangsu Province, China, and belongs to an indica two-line hybrid rice variety. The rice seeds were disinfected with 70% ethanol for 5 minutes, then disinfected with 5% sodium hypochlorite for 30 minutes, and rinsed with sterile distilled water for 5-6 times. After disinfection, the seeds were transferred into a beaker containing a seed soaking agent respectively (the seed soaking agent was a solution of Na₂SeO₃, with a selenium element concentration of 1 mg/L; the mass-volume ratio of the seeds to the seed soaking agent was 1 g: 5 mL). The top of the beaker was covered with clean paper. The beaker was left to stand for 24 h without light (25±1° C.). After 24 h, the seeds were withdrawn from the solution and rinsed with distilled water for 2 to 5 times, and dried by keeping in between two layers of filter paper followed by under bright sunlight till it became completely dry i.e. ±10% of initial weight. The dried seeds was then placed in a petri dish covered with moist filter paper and pre-germinated for 3 days. When the buds of seeds are longer than 2 mm, the seeds could be sowed. The germinated seeds were sowed into plastic pots (bottom diameter 20 cmx aperture diameter 30 cm×height 20 cm) filled with 5 kg of test soil, three pockets per pot, and one plant per pocket. Moisture content and fertilizer were controlled as follows: before sowing, 2.5 g of urea and 1.0 g of dipotassium hydrogen phosphate were applied to each pot at a time, respectively corresponding to 1200 kg/ha and 480 kg/ha in the field; flooding 2-3 cm was kept throughout the growth period. Other management measures were basically the same as the field.

TABLE 1
Basic physical and chemical properties of soil to be tested

| | |
|---|---|
| pH | 5.38 |
| Organic matter g/kg | 29.5 |
| Available nitrogen mg/kg | 126.74 |
| Available phosphorus mg/kg | 168.93 |
| Available potassium mg/kg | 113.00 |
| CEC cmol/kg | 9.15 |
| Clay particle % | 43.04 |
| Silt particle % | 14.84 |
| Sand particle % | 42.12 |
| Total Cd mg/kg | 0.80 |
| Available Cd mg/kg | 0.20 |

### Example 2

A method was performed similar to Example 1, except that the seed soaking agent was a solution of Na₂SeO₃ with a selenium element concentration of 5 mg/L.

### Example 3

A method was performed similar to Example 1, except that the seed soaking agent was a silicic acid suspension with a silicon element concentration of 2 mmol/L, and the seed soaking agent was prepared as follows: silicic acid and water were mixed, and the resulting mixture was added into an ultrasonic cleaner, and sonicated in a water bath at 30° C. for 7.5 hours, obtaining the seed soaking agent.

### Example 4

A method was performed similar to Example 3, except that the silicon element concentration in the seed soaking agent was 4 mmol/L.

### Example 5

A method was performed similar to Example 1, except that the seed soaking agent was a solution of ZnSO₄·7H₂O with a zinc element concentration of 0.5 mol/L.

### Example 6

A method was performed similar to Example 1, except that the seed soaking agent was a mixture solution of FeSO₄·7H₂O and Na₂SeO₃, with a selenium element concentration of 5 mg/L and an iron element concentration of 4 mg/L.

### Example 7

A method was performed similar to Example 1, except that the seed soaking agent was a mixture of Na₂SeO₃ solution and silicic acid suspension, with a selenium element concentration of 5 mg/L and a silicon element concentration of 2 mmol/L.

### Example 8

A method was performed similar to Example 1, except that the seed soaking agent was a mixture solution of Na₂SeO₃ and ZnSO₄·7H₂O, with a selenium element concentration of 5 mg/L and a zinc element concentration of 0.5 mol/L.

### Example 9

A method was performed similar to Example 1, except that the seed soaking agent was a solution of FeSO₄·7H₂O, with an iron element concentration of 4 mg/L.

### Comparative Example 1

A method was performed similar to Example 1, except that the seed soaking agent was clear water.

### Comparative Example 2

A method was performed similar to Example 1, except that the selenium element concentration in the seed soaking agent was 20 mg/L.

### Use Example 1

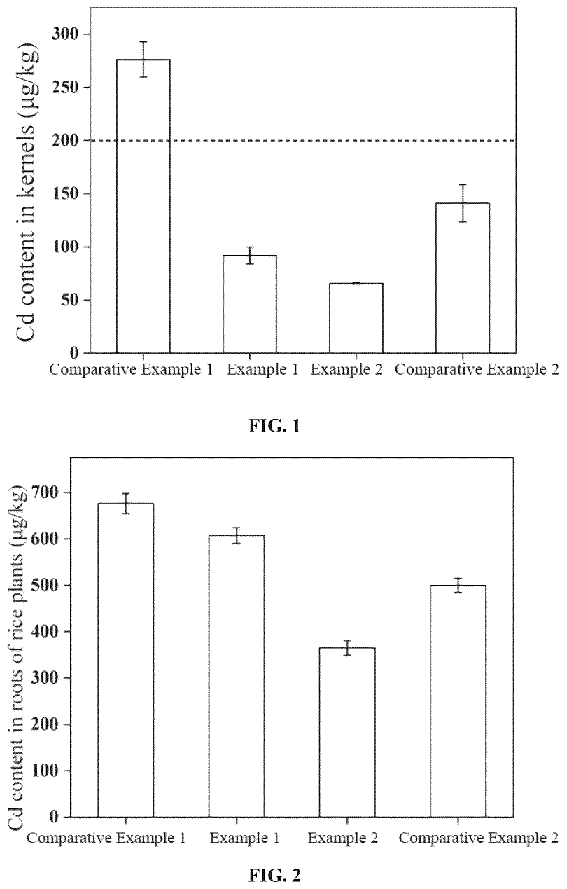

Examples 1 and 2 and Comparative Examples 1 and 2, with four different concentrations, were repeated three times (3 pots) respectively. In maturity stage of rice, roots, stems, leaves and kernels of rice plants grown from differently-treated seeds in each pot were harvested, and then rinsed with deionized water. The rinsed samples were killed at 105° C. for 30 minutes, and then were oven-dried to constant weights at 75° C. until that the weight thereof was constant. The dried samples were weighed, and crushed. For the analysis of Cd in rice, the crushed brown rice sample was digested with HNO₃—HClO₄ in an electric hot plate until a clear solution was obtained. The resulting clear solution was subjected to a test by utilizing inductively coupled plasma mass spectrometry ICP-MS. In the digestion process, a standard substance spinach (GBW10015) analysis and a reagent blank analysis were conducted, in combination with repetition analyses, to verify the accuracy and precision of the digestion procedure. The test results are shown in Table 2 and FIGS. 1 to 4.

TABLE 2
Cd content in parts of rice in maturity stage after treatments
with seed soaking agents of different concentrations

| | |
|---|---|
| Treated | Cd content (μg/kg) |

| groups | Kernels | Roots | Stems | Leaves |
|---|---|---|---|---|
| Example 1 | 92.01 | 607.27 | 99.25 | 89.90 |
| Example 2 | 65.64 | 365.00 | 94.59 | 52.63 |
| Comparative | 276.06 | 676.13 | 392.83 | 241.46 |
| Example 1 | | | | |
| Comparative | 140.94 | 499.81 | 185.02 | 98.94 |
| Example 2 | | | | |

It can be seen from Table 2 and FIG. 1 that in the Cd-contaminated (0.8 mg/kg) soil, the Cd content in rice kernels obtained from treated seeds was significantly decreased, with a decrease of 49%-45%, compared with the blank control without soaking the rice seeds. In addition, by comparisons among seed soaking agents with different Se concentrations, it can be concluded that the seed soaking agent according to the present disclosure has an better effect when the water-soluble Se concentration is in the range of 1-5 mg/L. Then Cd content of rice kernels is decreased to 0.06-0.1 mg/kg, which is significantly lower than National Food Safety Standard-pollutant limit standard in food of 0.2 mg/kg. While the Cd content of rice kernels in Comparative Example 2 is also lower than the national food safety standard, but the Se element concentration in the seed soaking agent is too high, which would not only increase the production cost, but also have a toxic effect on the growth of rice.

It can be seen from Table 2 and FIG. 2 that, the Cd content in roots of rice plants grown from treated seeds was significantly decreased, with a decrease of 10% to 76%, compared with the blank control group in which the rice seeds were soaked in clear water. In addition, by comparison among seed soaking agents with different Se concentrations, it can be concluded that the seed soaking agent according to the present disclosure has the best effect when the water-soluble Se concentration is 5 mg/L. Then the Cd content in roots of rice was significantly lower than those of the control groups. It indicates that in rice plants grown from the soaked seed with a Se-containing solution the absorption of Cd by the roots is reduced.

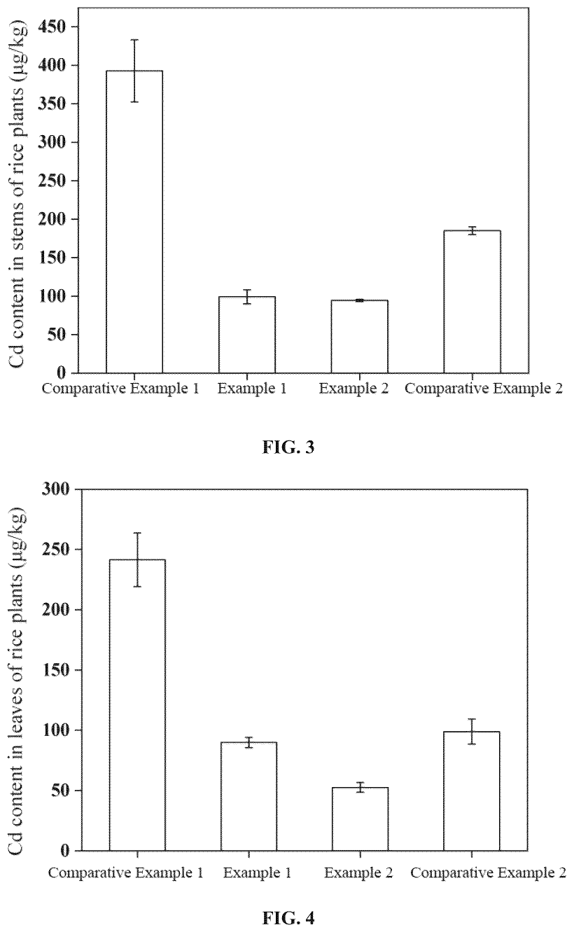

It can be seen from Table 2 and FIG. 3 that, the Cd content in stems of the rice plants grown from treated seeds was significantly decreased, with a decrease of 53% to 76%, compared with the blank control group in which rice seeds were soaked with clear water. In addition, by comparison among seed soaking agents with different Se concentrations, it can be concluded that the seed soaking agent according to the present disclosure has the best effect when the water-soluble Se concentration is in the range of 1-5 mg/L. Then the Cd contents in stems of rice plants were significantly lower than those of the blank control groups. It indicates that in rice plants grown from the soaked seeds with an Se-containing solution the transfer of Cd from the root to the stem is reduced.

From Table 2 and FIG. 4, it can be seen that the Cd content in leaves of rice plants grown from treated seeds was significantly decreased, with a decrease of 59%-78%, compared with the blank group in which the rice seeds were soaked with clear water. In addition, by comparison among seed soaking agents with different Se concentrations, it can be concluded that the seed soaking agent according to the present disclosure has the best effect when the water-soluble Se concentration is 5 mg/L. Then the Cd contents in leaves of rice plants are significantly lower than those of the blank control groups. It indicates that in rice plants grown from the soaked seeds with an Se-containing solution the transport of Cd to the above-ground portion is reduced.

### Use Example 2

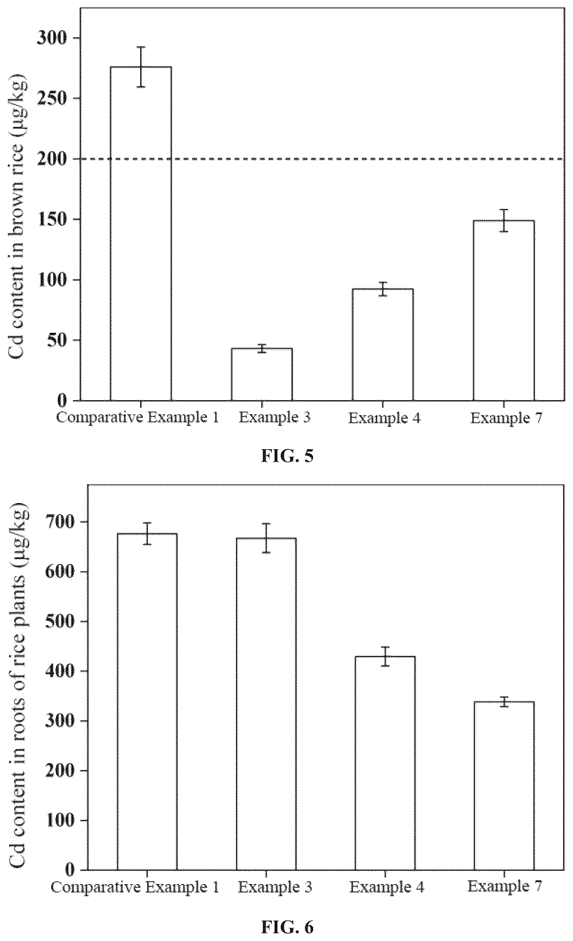

The rice plants and brown rice in Examples 3, 4 and 7 and Comparative Example 1 were analyzed by the same method as described in Use Example 1. The test results are shown in Table 3 and FIGS. 5-8.

TABLE 3
Cd contents in parts of rice plants in maturity
stage after treatments with seed soaking agents
of different concentrations and different methods

| | |
|---|---|
| Treated | Cd content (μg/kg) |

| groups | Kernels | Roots | Stems | Leaves |
|---|---|---|---|---|
| Comparative | 276.06 | 676.13 | 392.83 | 241.46 |
| Example 1 | | | | |
| Example 3 | 43.17 | 667.41 | 78.35 | 27.73 |
| Example 4 | 92.37 | 429.43 | 112.13 | 32.97 |
| Example 7 | 148.95 | 338.34 | 223.07 | 99.99 |

It can be seen from Table 3 and FIG. 5 that in the Cd-contaminated (0.8 mg/kg) soil, the Cd contents in rice kernels of rice plants grown from treated seeds were significantly decreased, with a decrease of 46% to 84%, compared with the blank control group in which the rice seeds were soaked with clear water. In addition, by comparisons among seed soaking agents with different Si concentrations and combinations, it can be concluded that the rice seed soaking agent according to the present disclosure has a better effect when the water-soluble Si concentration is 2 mmol/L. Then the Cd content in rice kernels is decreased to 0.04 mg/kg, which is significantly lower than the national food safety standard-0.2 mg/kg.

It can be seen from Table 3 and FIG. 6 that the Cd content in roots of rice plants grown from treated seeds in part of examples was decreased, with a decrease of 1% to 50%, compared with the blank control in which the rice seeds were soaked in clear water.

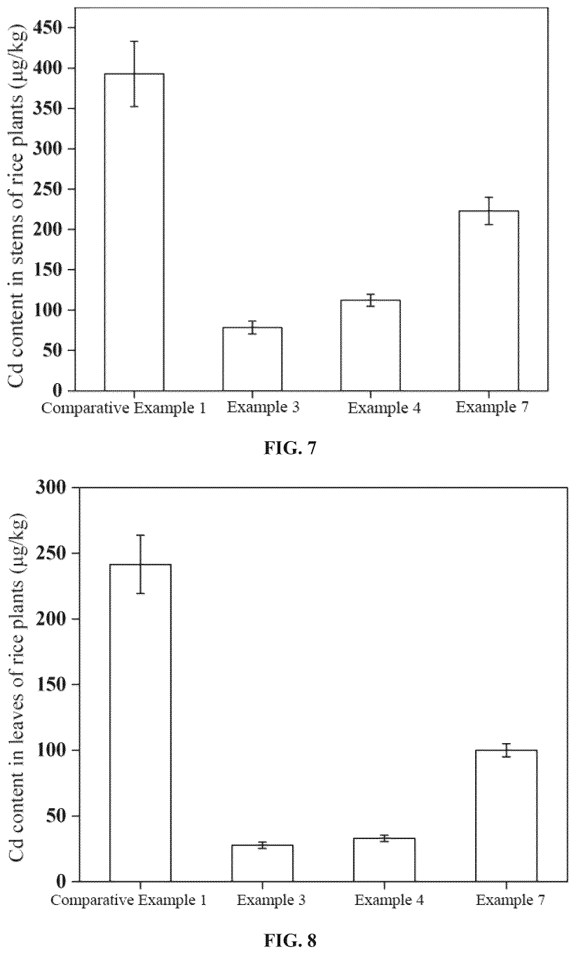

It can be seen from Table 3 and FIG. 7 that the Cd contents in stems of rice plants grown from treated seeds were significantly decreased, with a decrease of 43% to 80%, compared with the blank control in which the rice seeds were soaked in clear water. In addition, by comparisons among seed soaking agents with different Si concentrations and different combinations, it can be concluded that the rice seed soaking agent according to the present disclosure has the best effect when the water-soluble Si concentration is 2 mmol/L. Then the Cd contents in stems of rice plants are significantly lower than that of the blank control group. In conjunction with the Cd contents in roots of rice plants grown from treated seeds, it indicated that in rice plants grown from the soaked seeds with a Si containing solution, the transfer of Cd from the root to the stem is reduced.

From Table 3 and FIG. 8, it can be seen that the Cd contents in leaves of rices plants grown from treated seeds are significantly decreased, with a decrease of 59% to 89%, compared with the blank control group in which the seeds are soaked with clear water. In addition, by comparisons among seed soaking agents with different Si concentrations and different combinations, it can be concluded that the rice seed soaking agent according to the present disclosure has the best effect when the water-soluble Si concentration is 2 mmol/L. Then the Cd contents in leaves of rice plants are significantly lower than that of the blank control group. It indicates that in rice plants grown from the soaked seeds with a Si containing solution the transport of Cd to the above-ground portions is reduced.

### Use Example 3

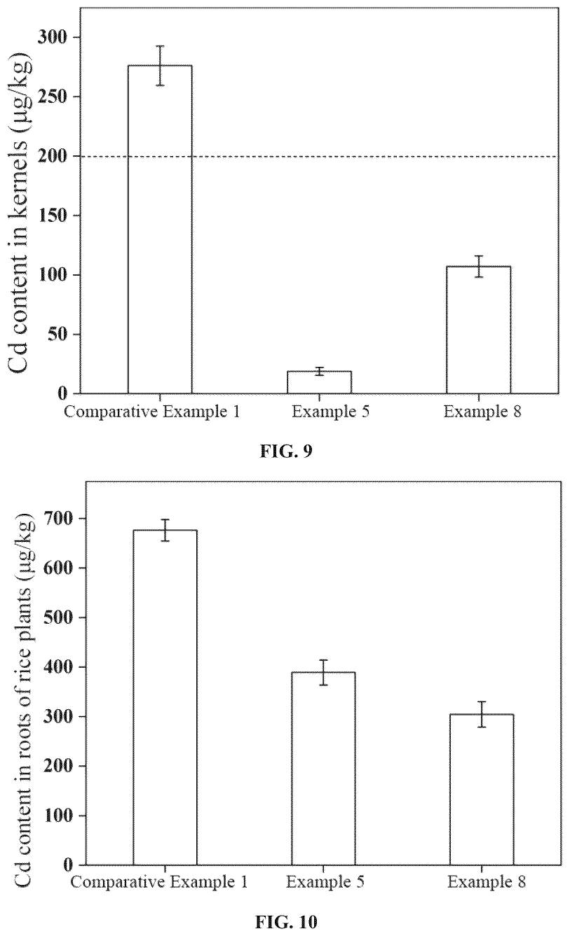

The rice plants and brown rice in Examples 5 and 8 and Comparative Example 1 were analyzed by the same method as described in Use Example 1. The test results are shown in Table 4 and FIGS. 9-12.

TABLE 4
Cd contents in parts of rice plants in maturity
stage after different seed-soakings

| | |
|---|---|
| Treated | Cd content (μg/kg) |

| groups | Kernels | Roots | Stems | Leaves |
|---|---|---|---|---|
| Comparative | 276.06 | 676.13 | 392.83 | 241.46 |
| Example 1 | | | | |
| Example 5 | 18.80 | 388.98 | 36.85 | 9.37 |
| Example 8 | 107.04 | 304.54 | 111.53 | 92.70 |

It can be seen from Table 4 and FIG. 9 that in the Cd-contaminated (0.8 mg/kg) soil, the Cd content in rice kernels obtained from treated seeds is significantly decreased, with a decrease of 61%-93%, compared with the blank control group in which the rice seeds were soaked with clear water. In addition, by comparisons among different seed-soakings with Zn, it can be concluded that the seed soaking agent according to the present disclosure has a better effect when the water-soluble Zn concentration is 0.5 mol/L. Then the Cd content of rice kernels is decreased to 0.018 mg/kg, which is significantly lower than National Food Safety Standard—0.2 mg/kg.

It can be seen from Table 4 and FIG. 10 that, the Cd contents in roots of rice plants grown from treated seeds are significantly decreased, with a decrease of 43% to 55%, compared with the blank control group in which the rice seeds were soaked with clear water. In addition, by comparisons among different seed-soakings with Zn, it can be concluded that the seed soaking agent according to the present disclosure has the best effect when the water-soluble Se concentration is 0.5 mol/L. Then the Cd contents in roots of rice plants are significantly lower than that of the control group. It indicates that in rice plants grown from the soaked seed with a Zn-containing solution the absorption of Cd by the roots is reduced.

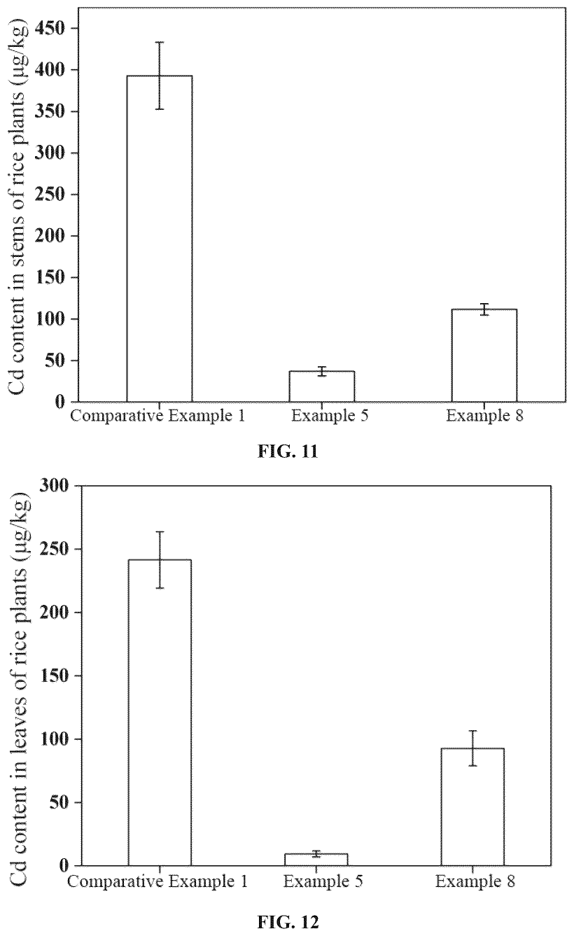

It can be seen from Table 4 and FIG. 11 that, the Cd contents in stems of the rice plants grown from treated seeds are significantly decreased, with a decrease of 72% to 91%, compared with the blank control group in which rice seeds were soaked with clear water. In addition, by comparisons among different seed-soakings with Zn, it can be concluded that the seed soaking agent according to the present disclosure has the best effect when the water-soluble Zn concentration is 0.5 mol/L. Then the Cd contents in stems of rice plants are significantly lower than that of the blank control group. It indicates that in rice plants grown from the soaked seeds with an Zn-containing solution the transfer of Cd from the root to the stem is reduced.

From Table 4 and FIG. 12, it can be seen that the Cd contents in leaves of rice plants grown from treated seeds are significantly decreased, with a decrease of 62%-96%, compared with the blank group in which the rice seeds were soaked with clear water. In addition, by comparisons among different seed-soakings with Zn, it can be concluded that the seed soaking agent according to the present disclosure has the best effect when the water-soluble Zn concentration is 0.5 mol/L. Then the Cd contents in leaves of rice plants are significantly lower than that of the blank control group. It indicates that in rice plants grown from the soaked seeds with a Zn-containing solution the transport of Cd to the above-ground portion is reduced.

### Use Example 4

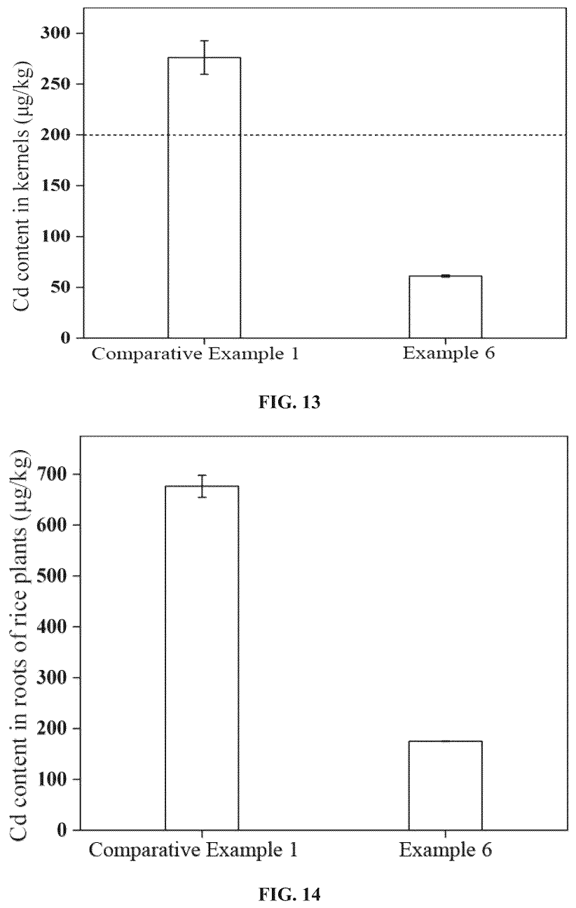

The rice plants and brown rice in Examples 6 and Comparative Example 1 were analyzed by the same method as described in Use Example 1. The test results are shown in Table 5 and FIGS. 13-16.

TABLE 5
Cd contents in parts of rice plants in maturity
stage after different seed-soakings

| | |
|---|---|
| Treated | Cd content (μg/kg) |

| groups | Kernels | Roots | Stems | Leaves |
|---|---|---|---|---|
| Comparative | 276.06 | 676.13 | 392.83 | 241.46 |
| Example 1 | | | | |
| Example 6 | 61.11 | 174.81 | 102.73 | 51.34 |

It can be seen from Table 5 and FIG. 13 that in the Cd-contaminated (0.8 mg/kg) soil, compared with the blank control group in which the rice seeds were soaked with clear water, the seed soaking agent according to the present disclosure has the best effect when the water-soluble Fe concentration is 4 mg/L, and the water-soluble Se concentration is 5 mg/L. Then the Cd content in rice kernels is decreased to 0.061 mg/kg, which is significantly lower than National Food Safety Standard—0.2 mg/kg.

It can be seen from Table 5 and FIG. 14 that the Cd contents in roots of rice plants grown from treated seeds are significantly decreased, with a decrease of 57% to 74%, compared with the blank control group in which the rice seeds were soaked with clear water. In addition, the seed soaking agent according to the present disclosure has the best effect when the water-soluble Fe concentration is 4 mg/L, and the water-soluble Se concentration is 5 mg/L. Then the Cd contents in roots of rice plants are significantly lower than that of the control group. It indicates that in rice plants grown from the soaked seed with an Fe—Se-containing solution the absorption of Cd by the roots is reduced.

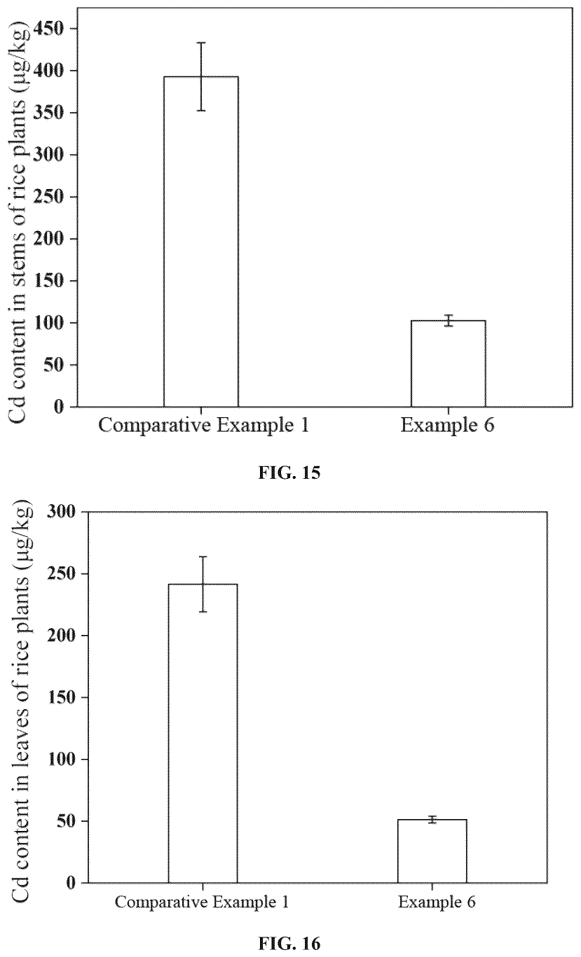

It can be seen from Table 5 and FIG. 15 that the Cd contents in stems of the rice plants grown from treated seeds are significantly decreased, with a decrease of 36% to 74%, compared with the blank control group in which rice seeds were soaked with clear water. In addition, the seed soaking agent according to the present disclosure has the best effect when the water-soluble Fe concentration is 4 mg/L, and the water-soluble Se concentration is 5 mg/L. Then the Cd contents in stems of rice plants are significantly lower than that of the blank control group. It indicates that in rice plants grown from the soaked seeds with an Fe—Se-containing solution the transfer of Cd from the root to the stem is reduced.

From Table 5 and FIG. 16, it can be seen that the Cd contents in leaves of rice plants grown from treated seeds are significantly decreased, with a decrease of 31%-79%, compared with the blank group in which the rice seeds were soaked with clear water. In addition, the seed soaking agent according to the present disclosure has the best effect when the water-soluble Fe concentration is 4 mg/L, and the water-soluble Se concentration is 5 mg/L. Then the Cd contents in leaves of rice plants are significantly lower than that of the blank control group. It indicates that in rice plants grown from the soaked seeds with a Zn-containing solution the transport of Cd to the above-ground portion is reduced.

### Use Example 5

A low-labor intensity and simple method for reducing Cd content of rice was performed by the following field experiment:

Land for experiment is located in a contaminated area, Guixi, Jiangxi, China (the total Cd content in soil is 0.85 mg/kg), and in the region main type of soil is paddy soil developed from parent material of river alluvium, in which the main contaminant is heavy metal Cd. Basic physical and chemical properties thereof are shown in Table 6. According to “Soil Environmental Quality Risk Control Standard for Soil Contamination of Agricultural Land (GB 15618-2018), the Cd content in soil between the risk screening value (0.3 mg/kg) and risk intervention value (1.5 mg/kg) of Cd in soil of agricultural land represents slight and moderate contamination of soil. 80% of Cd-contaminated cultivated land in China was within this range.

TABLE 6
Basic physical and chemical properties of soil to be tested

| | |
|---|---|
| pH | 5.23 |
| Organic matter g/kg | 25.21 |
| Available nitrogen mg/kg | 151.90 |
| Available phosphorus mg/kg | 31.29 |
| Available potassium mg/kg | 50.00 |
| Total cadmium mg/kg | 0.85 |
| Available Cd mg/kg | 0.25 |

The specific procedures were as follows: This experiment adopted a single-factor difference and repeated design. Two kinds of rice were selected, i.e. Chuangliangyou 276 (which has been verified effective in the pot experiments) and local commonly used Wuyou Huazhan. The seeds were soaked and pre-germinated by the methods similar to Use Example 1, except that the seed soaking agent used was different. There were 10 treatments with three replications, totaling 30 plots, each with an area of 20 m² (4 m×5 in), arranged in randomized groups, with PVC boards separating the plots to prevent the test results from being affected by stormwater runoff. The treatments in this example were as follows:

TABLE 7
Treatments in this experiment

| Group | Seed soaking agents | Rice varieties |
|---|---|---|
| 1 | Comparative Example 1 | Chuangliangyou 276 |
| 2 | Example 1 | Chuangliangyou 276 |
| 3 | Example 3 | Chuangliangyou 276 |
| 4 | Example 5 | Chuangliangyou 276 |
| 5 | Example 9 | Chuangliangyou 276 |
| 6 | Comparative Example 1 | Wuyou Huazhan |
| 7 | Example 1 | Wuyou Huazhan |
| 8 | Example 3 | Wuyou Huazhan |
| 9 | Example 5 | Wuyou Huazhan |
| 10 | Example 9 | Wuyou Huazhan |

Note:
Seed soaking agents in Table 7 mean that the soaking agents used in different treatments are the soaking agents prepared in the corresponding examples or comparative example.

As described in Example 1, seeds were soaked, pre-germinated, and sown. In terms of the dry weight of seeds before soaking, the seeds were sowed in an amount of 0.1667 kg/ha. Moisture content and fertilizer were controlled as follows: before sowing cultivated areas were leveled, and urea and dipotassium hydrogen phosphate were applied in an amount of 200 kg/ha and 480 kg/ha, respectively; flooding 2-3 cm was kept throughout the growth period; other management measures were basically the same as the production of large area.

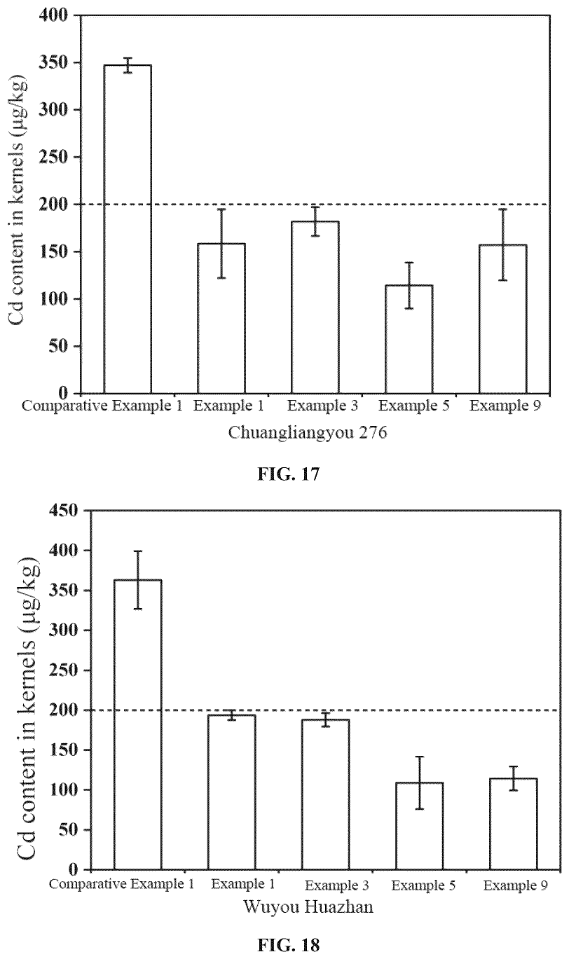

In maturity stage of rice, the rice kernel samples in each district for each treatment were harvested by a five-point sampling method. After washing with deionized water, the samples were killed at 105° C. for 30 minutes, and then oven-dried at 75° C. to constant weights. The dried samples were weighed, and crushed. The crushed kernel samples were digested with HNO₃—HClO₄ in an electric hot plate until a clear solution was obtained. The resulting clear solution was subjected to a test by utilizing inductively coupled plasma mass spectrometry ICP-MS. In the digestion process, a standard substance spinach (GBW10015) analysis and a reagent blank analysis were conducted, in combination with repetition analyses, to verify the accuracy and precision of the digestion procedure. The results are shown in Table 8 and FIGS. 17-18.

TABLE 8
Cd content in kernels of different rice varieties after treatments
with seed soaking agents with different concentrations

| | |
|---|---|
| Treated | Cd content (μg/kg) |

| group | Chuangliangyou 276 | Wuyou Huazhan |
|---|---|---|
| Comparative | 346.96 | 362.92 |
| Example 1 | | |
| Example 1 | 158.41 | 193.60 |
| Example 3 | 181.78 | 193.79 |
| Example 5 | 114.22 | 108.92 |
| Example 9 | 157.13 | 114.32 |

From Table 8 and FIGS. 17-18, it can be seen that in Cd-contaminated (0.85 mg/kg) soil, for two different rice varieties, the rice seed soaking agent according to the present disclosure has a significant effect when the water-soluble Se concentration is 1 mg/L, the water-soluble Si concentration is 2 mmol/L, the water-soluble Zn concentration is 0.5 mol/L, and the water-soluble Fe concentration is 4 mg/L, compared with the blank control group in which the rice seeds were soaked with clear water. Then the Cd contents of rice kernels were lower than National safety standard-0.2 mg/kg. It is consistent with the results of the pot experiment. Therefore, the seed soaking agent could be promoted and used.

### Use Example 6

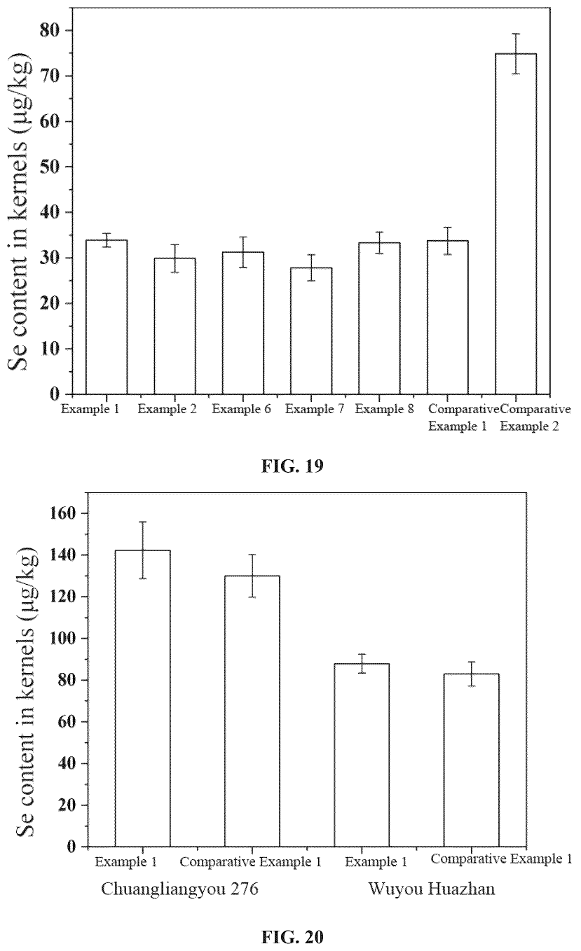

In maturity stage of rice, the rice kernels of each pot treated with different seed soaking agents in Examples 1, 2, 6, 7, 8 and Comparative Examples 1 and 2 were harvested. The contents of Se in kernels harvested after different treatments was determined by inductively coupled plasma mass spectrometry in GB5009.268-2016 (ICP-MS). The results are shown in FIG. 19 and Table 9.

TABLE 9
Se contents in kernels after treatments with seed
soaking agents with different concentrations

| Seed soaking agents | Se content (μg/kg) |
|---|---|
| Example 1 | 33.89 |
| Example 2 | 29.87 |
| Example 6 | 31.25 |
| Example 7 | 27.81 |
| Example 8 | 33.31 |
| Comparative Example 1 | 33.74 |
| Comparative Example 2 | 74.82 |

Note:
Seed soaking agents in Table 9 mean that the soaking agents used in different treatments are the soaking agents in the corresponding examples or comparative examples.

It can be seen from FIG. 19 and Table 9 that after soaking with seed soaking agents with different Se element concentrations, the Se element content in kernels harvested is significantly increased only when the water-soluble Se concentration is 20 mg/L (Comparative Example 2 group). Also, there is no significant difference between the Se element content in brown rice harvested after soaking seeds with a solution with a suitable Se element concentration and that of Comparative Example 1 in which seeds were soaked with clear water. This is because after soaking rice seeds absorbed Se element, and converted Se element into endogenous organic Se, which reduces the absorption ability of rice to exogenous selenium element. Therefore, for seeds soaked with low-concentration Se element, the selenium content in kernels of mature plants do not change significantly. In addition, in seeds soaked with seed soaking agents, Se exists in the form of organic Se, which is non-toxic and harmless.

From the pot experiment, it can be seen that after soaking seeds with a solution with a suitable Se element concentration, the harvested rice poses no risk to health of the human body.

### Use Example 7

In maturity stage of rice, the rice kernel samples in each district for each treatment were harvested by a five-point sampling method. The contents of Se in kernels harvested after soaking the seeds of different rice varieties respectively with the seed soaking agents of Example 1 and Comparative Example 1 were determined by inductively coupled plasma mass spectrometry (ICP-MS) according to GB5009.268-2016. The results are shown in FIG. 20 and Table 10.

TABLE 10
Se content in kernels of different rice varieties after soaking

| Seed soaking agents | Rice varieties | Se content (μg/kg) |
|---|---|---|
| Example 1 | Chuangliangyou 276 | 142.24 |
| Comparative | Chuangliangyou 276 | 129.97 |
| Example 1 | | |
| Example 1 | Wuyou Huazhan | 87.89 |
| Comparative | Wuyou Huazhan | 82.96 |
| Example 1 | | |

Note:
Seed soaking agents in Table 9 mean that the soaking agents used in different treatments are the seed soaking agents in the corresponding examples or comparative examples.

It can be seen from FIG. 20 and Table 10 that in the field experiment, for different rice varieties, the rice seed soaking agent in Example 1 of the present disclosure has no significant effect on the Se element content in kernels (brown rice) of mature plant, which is consistent with the result of the pot experiment. In 2011, in accordance with the provisions of “Food Safety Law” and “Measures for the Administration of National Food Safety Standards”, approved by the National Food Safety Standards Review Committee, it is now decided to cancel selenium index (Se limit standard of 0.3 mg/kg) in “Limits for Contaminants in Foods” (GB2762-2005). Also, Se is essential for humans and animals, and the Se content in most rice is about 40 μg/kg, which is lower than China's food hygiene standards. According to average food consumption structure in China, 206 kg of cereal crops such as rice and wheat is consumed per capita per year. Assuming that all cereal crops are rice, adults consume 0.564 kg of rice per day. By calculation, it can be known that the daily selenium intake for adults is 80 μg as for rice harvested from Se-soaked Chuangliangyou 276 rice variety, which is much larger than the minimum daily intake of 40 μg recommended by the National Nutrition Association for adults, which meets market demand. In addition, in the soaked seeds, Se exists in the form of organic Se, which poses no risk to the health of human body.

From the field experiment, it can be known that after soaking with a solution with a suitable Se element concentration, the harvested rice poses no risk to the health of human body and has higher nutritional value.

In summary, by mixing a seed with a seed soaking agent containing a trace element required by plants in a suitable concentration, the method according to the present disclosure could not only reduce the absorption of Cd by plant roots, but also reduce the transport of Cd from plant roots to other parts, thereby improving the resistance of plants to Cd. In addition, the method according to the present disclosure makes it possible to obtain rice with a Cd content not exceeding the standard by the lowest-cost and the most convenient method, and allow that brown rice from rice plant which is grown in Cd-contaminated soil has a Cd content significantly lower than the national food safety standards-0.2 mg/kg. Also, it saves a lot of manpower and material resources, and is completely suitable for popularization and use in the field of prevention and control technology of the heavy metal pollution in China's rice and other bulk agricultural products.

Although in the present disclosure, preferred embodiments have been disclosed above, it is not intended to limit the present disclosure. Anyone familiar with this technology could make various changes and modifications without departing from the spirit and scope of the present disclosure. Therefore, the protection scope of the present disclosure should be defined by the claims.

1. A seed soaking agent for reducing Cd content of rice, an active ingredient of which comprises a trace element required by plants,
wherein the trace element comprises one of selenium element, silicon element, zinc element, and iron element, or a mixture of selenium element with one selected from the group consisting of iron element, silicon element, and zinc element;
under the condition that the trace element is selenium element, in the seed soaking agent, a selenium element concentration is in the range of 0.5-6 mg/L;
under the condition that the trace element is silicon element, in the seed soaking agent, a silicon element concentration is in the range of 1.5-5 mmol/L;
under the condition that the trace element is zinc element, in the seed soaking agent, a zinc element concentration of is in the range 0.25-0.75 mol/L;
under the condition that the trace element is iron element, in the seed soaking agent, an iron element concentration is in the range of 3-5 mg/L;
under the condition that the trace element is a mixture of selenium element and iron element, in the seed soaking agent, a selenium element concentration is in the range of 4-6 mg/L, and an iron element concentration is in the range of 3-5 mg/L;
under the condition that the trace element is a mixture of selenium element and silicon element, in the seed soaking agent, a selenium element concentration is in the range of 4-6 mg/L, and a silicon element concentration is in the range of 1.5-5 mmol/L; and
under the condition that the trace element is a mixture of selenium element and zinc element, in the seed soaking agent, a selenium element concentration is in the range of 4-6 mg/L, and a zinc element concentration is in the range of 0.25-0.75 mol/L.

2. The seed soaking agent as claimed in claim 1, wherein
under the condition that the trace element comprises selenium element, a source of the selenium element comprises Na₂SeO₃;
under the condition that the trace element comprises silicon element, a source of the silicon element comprises silicic acid;
under the condition that the trace element comprises zinc element, a source of the zinc element comprises ZnSO₄·7H₂O;
under the condition that the trace element comprises iron element, a source of the iron element comprises FeSO₄·7H₂O.

3. A low-labor intensity and simple method for reducing Cd content of rice, comprising
mixing a seed and a seed soaking agent, and soaking the seed, to obtain a soaked seed;
sowing the soaked seed; and
reaping to obtain rice with a low Cd content,
wherein an active ingredient of the seed soaking agent comprises a trace element required by plants, said trace element comprises selenium element, silicon element, zinc element or iron element, or a mixture of selenium element and iron element, a mixture of selenium element and silicon element, or a mixture of selenium element and zinc element;
under the condition that the trace element is selenium element, in the seed soaking agent, a selenium element concentration is in the range of 0.5-6 mg/L;
under the condition that the trace element is silicon element, in the seed soaking agent, a silicon element concentration is in the range of 1.5-5 mmol/L;
under the condition that the trace element is zinc element, in the seed soaking agent, a zinc element concentration is in the range of 0.25-0.75 mol/L;
under the condition that the trace element is iron element, in the seed soaking agent, an iron element concentration is in the range of 3-5 mg/L;
under the condition that the trace element is a mixture of selenium element and iron element, in the seed soaking agent, a selenium element concentration is in the range of 4-6 mg/L, and an iron element concentration is in the range of 3-5 mg/L;
under the condition that the trace element is a mixture of selenium element and silicon element, in the seed soaking agent, a selenium element concentration is in the range of 4-6 mg/L, and a silicon element concentration is in the range of 1.5-5 mmol/L;
under the condition that the trace element is a mixture of selenium element and zinc element, in the seed soaking agent, a selenium element concentration is in the range of 4-6 mg/L, and a zinc element concentration is in the range of 0.25-0.75 mol/L.

4. The method as claimed in claim 3, wherein a mass-volume ratio of the seed to the seed soaking agent is in the range of 1 g:(4-7) mL; the seed has a moisture content of 12%-14%.

5. The method as claimed in claim 3, wherein
under the condition that the trace element comprises selenium element, a source of the selenium element comprises Na₂SeO₃;
under the condition that the trace element comprises silicon element, a source of the silicon element comprises silicic acid;
under the condition that the trace element comprises zinc element, a source of the zinc element comprises ZnSO₄·7H₂O;
under the condition that the trace element comprises iron element, a source of the iron element comprises FeSO₄·7H₂O.

6. The method as claimed in claim 5, wherein under the condition that the trace element is silicon element, the seed soaking agent is prepared by a process comprising
mixing silicic acid with water, and sonicating the resulting mixture to obtain the seed soaking agent;
under the condition that the trace element is a mixture of selenium element and silicon element, the seed soaking agent is prepared by a process comprising
mixing silicic acid with water, and sonicating the resulting mixture, to obtain a silicic acid suspension; and
mixing the silicic acid suspension with Na₂SeO₃, to obtain the seed soaking agent.

7. The method as claimed in claim 6, wherein the sonicating is conducted at a temperature of 30° C.; the sonicating is conducted for 7-8 hours.

8. The method as claimed in claim 3, further comprising after mixing the seed and the seed soaking agent, leaving the seed to stand, wherein leaving the seed to stand is conducted in the dark at a temperature of 24-29° C. for 24-26 hours.

9. The method as claimed in claim 8, further comprising before sowing the soaked seed, pre-germinating the soaked seed, wherein pre-germinating the soaked seed is conducted for 3-5 days.

10. The method as claimed in claim 3, further comprising before mixing the seed and the seed soaking agent, disinfecting the seed, wherein disinfecting the seed comprises
disinfecting the seed with an aqueous ethanol solution, and an aqueous sodium hypochlorite solution in sequence to obtain a disinfected seed, and rinsing the disinfected seed with sterile water,
wherein the aqueous ethanol solution has an ethanol volume concentration of 65%-75%, and the aqueous sodium hypochlorite solution has an available chlorine content of 5%-7%.

11. The method as claimed in claim 10, wherein disinfecting the seed with an aqueous ethanol solution is conducted for 4-6 min; disinfecting the seed with an aqueous sodium hypochlorite solution is conducted for 25-35 min.

12. (canceled)

13. The method as claimed in claim 4, wherein
under the condition that the trace element comprises selenium element, a source of the selenium element comprises Na₂SeO₃;
under the condition that the trace element comprises silicon element, a source of the silicon element comprises silicic acid;
under the condition that the trace element comprises zinc element, a source of the zinc element comprises ZnSO₄·7H₂O;
under the condition that the trace element comprises iron element, a source of the iron element comprises FeSO₄·7H₂O.

14. The method as claimed in claim 3, the rice is grown in Cd-contaminated soil.
